(19) United States
(12) Patent Application Publication
(10) Pub. No.: US 2011/0041892 A1
(43) Pub. Date: Feb. 24, 2011

(54) Heat sink system for large-size photovoltaic receiver

(76) Inventors: Alexander Levin, Binyamina (IL); Hanan Levin, Tel-Aviv (IL)

Correspondence Address: Alexander Levin, 5A Shvil Hachalav St., Binyamina, 30500, IL

(21) Appl. No.: 12/583,447

(22) Filed: Aug. 21, 2009

(51) Int. Cl. H01L 31/024; H01L 31/052

(52) U.S. Cl. 136/246; 257/E31.131

(57) ABSTRACT

An invention proposes a heat sink system for large-size photovoltaic receivers of tower-type solar power stations with application of an array of heliostats intended to concentrate solar radiation on the photovoltaic receiver.

The heat sink system is designed as a two-phase thermo-siphon and it can ensure a stable temperature on all photovoltaic cells installed on the large-size receiver with very small deviations of the temperatures from one photovoltaic cell to another.

### STATEMENT REGARDING FEDERALLY SPONSORED RESEARCH

Not applicable.

### BACKGROUND OF THE INVENTION

This invention proposes a heat sink system for large-size photovoltaic receivers of tower-type solar power stations with application of an array of heliostats intended to concentrate solar radiation on the photovoltaic receiver.

The problem of effective chilling of photovoltaic cells installed on a large-size receiver presents a serious technical challenge. Significant deviations in temperatures of different PV cells cause significant decrease in efficiency of the entire photovoltaic receiver.

US patent application No. 20070089775 describes a photovoltaic cell module for a receiver of solar radiation-based electrical power generating system. The module includes an assembly for extracting heat from the photovoltaic cells. The assembly includes a coolant chamber positioned behind and in thermal contact with the exposed surface of the photovoltaic cells. The coolant chamber includes an inlet for a coolant and an outlet for heated coolant. The assembly also includes a plurality of beads, rods, bars or balls of high thermal conductivity material in the coolant chamber that are in thermal contact with the photovoltaic cells and each other and together have a large surface area for heat transfer and define a three dimensional labyrinth that can conduct heat therethrough away from the photovoltaic cell or cells.

In particular, the applicant of this patent application has found that the above-described cell module makes it possible to extract sufficient heat generated by incident concentrated solar radiation so that the temperature difference between the inlet coolant temperature and the front faces of the photovoltaic cells is less than 40.degree. C, typically less than 30 degree C., more typically less than 25 degree C., and in recent test work less that 20 degree C., and that this result can be achieved with a low pressure drop of coolant, typically less than 100 kPa, typically less than 60 kPa, and more typically less than 40 kPa across the coolant inlet and coolant outlet of the cell module. The low pressure drop is an important consideration because it means that it is possible to minimize the energy requirements for circulating coolant through the module.

However, this technical solution cannot provide the temperature difference in the range of some Celsius degrees. In addition, there is a need in pumping means for circulating the coolant.

US patent application No. 20080314437 describes a multi heliostat concentrating (MHC) system for utilizing sun energy, which has at least on MHC module. A MHC module has at least one optical concentrator having a focusing reflective surface, aperture and an optical axis. A plurality of heliostats, which are preferably located symmetrically relative to the optical axis of an optical concentrator simultaneously reflect sun radiation towards its aperture. Flux error correcting a flux homogenizing device disposed at the focal region of an optical concentrator provides for further concentrating and homogenizing the flux of the focused sun radiation. A receiver preferably comprising concentrated photovoltaic cells and an optional passive heat-sink provides for efficiently and economically generating electrical power.

This patent application does not give description of the passive heat sink system.

Therefore, application of two-phase thermo-siphon system for cooling the large-size photovoltaic receiver seems an attractive technical solution.

However, there are some technical problems to be solved for such two-phase thermo-siphon system:

1. It is necessary to provide permanent wetting of the rear side of an entire large-size metal plate with the photovoltaic cells installed on its forward side. This wetting should be by a low-boiling working medium (for example—acetone).
2. It is necessary that the working pressure in the evaporation chamber is very close to atmospheric pressure in order to ensure mechanical intact of this evaporation chamber.
3. The working pressure in the evaporation chamber should remain very close to atmospheric pressure during the night time without solar radiation despite heat losses from the evaporation chamber of the two-phase thermo-siphon into the surroundings via the entire large-size metal plate with the photovoltaic cells installed on its forward side, and heat losses via the other walls of the evaporation chamber.

Detailed description of thermo-siphons with regulation of their working pressure is presented in a book: EFFECTIVE HEAT EXCHANGERS WITH APPLICATION OF TWO-PHASE THERMO-SIPHONS, I. L. Pioro et al., Naukova Dumka, Kiev 1991 (in Russian). However, this book does not propose a simple and reliable design of a two-phase thermo-siphon with the required features.

### BRIEF SUMMARY OF THE INVENTION

The invention provides design of a large-size heat sink for photovoltaic power stations constructed as a photovoltaic receiver mounted on a tower and an array of heliostats directing reflected solar radiation on the photovoltaic receiver.

The design has all required features described in the background of this invention.

An evaporation chamber of the two-phase thermo-siphon includes following elements:

1. a large-size metal plate with the photovoltaic cells installed on its forward side, the rear side of this metal plate is provided with a capillary structure;
2. a set of trays is mounted on the rear side of the large-size metal plate in such a way that the forward walls of these trays are formed by sections of the large-size metal plate with its capillary structure; the trays provide wetting of the adjacent areas of the capillary structure; in addition, there are overflow elements in construction of these trays, which ensure filling all the trays with the liquid working medium.

The evaporation chamber includes as well:

1. lateral and a rear walls with an outlet connection for removal of vapors of the working medium to a condenser and an inlet connection for return of condensate of the working medium from the condenser into the upper tray;
2. an array of a vertical sealed containers mounted on the lower lateral wall of the evaporation chamber; these sealed containers are filled with phase change material (PCM) with melting point some Celsius degree lower than the operating temperature of the working medium; the outer surfaces of these sealed containers are provided with capillary coatings;
3. a safety valve (or valves), which provides fluid communication of the evaporation chamber interior with the atmosphere in the case of significant deviation of pressure in the interior of the evaporation chamber from the atmospheric pressure;
4. layers of thermal insulation of the lateral and rear walls of the evaporation chamber.
5. some inlet and outlet connections for supply and removal of the working medium in its liquid and vaporous states.

In addition, the lower section of the evaporation chamber can be provided with an electrical heater in order to maintain required pressure in the interior of the evaporation chamber in hours without solar radiation.

An auxiliary pumping means is supplying the liquid working medium from the bottom section of the evaporator chamber into the inlet connection serving for feeding the liquid working medium into the upper tray. It allows to compensate for the condensate deficiency caused by condensation of the vaporous working medium on the walls of the evaporation chamber itself.

In another version of this invention, the liquid working medium fills the evaporation chamber until such level, that the lower section of the capillary coating is submerged into the liquid working medium. For certain technical parameters of the evaporation chamber pumping ability of the capillary coating compensates for the condensate deficiency caused by condensation of the vaporous working medium on the walls of the evaporation chamber itself.

The outer side of the large-size metal plate can be provided with stiffening ribs.

Vapors of the working medium are removed from the evaporation chamber via the outlet connection and enter into a condenser, which is designed as a heat exchanger of a recuperation type with condensing the vapors of the working medium by a surrounding air or by cooling water.

The evaporation chamber is provided with a sensor of internal pressure, which sends a signal to a control block. This control block in accordance with a value of difference between the internal pressure and atmospheric pressure regulates heat exchange rate in the condenser by adjusting flow rate of the cooling medium (surrounding air or cooling water).

Condensate is returning from the condenser into the evaporation chamber via its inlet connection.

In addition, there are a vacuum pump and a cooler-separator, which are in a fluid communication with the condensing side of the condenser and serves for removal of non-condensable gases from the interior of the two-phase thermo-siphon and recovery of the condensed working medium from the cooler-separator into the evaporation chamber.

Another version of design of the evaporation chamber allows to diminish or obviate at all supply of electrical energy for heating the liquid working medium at night time; this version allows at the same time to maintain internal pressure in the evaporation chamber very close to the atmospheric pressure.

Maintaining the evaporation pressure in this version is based on two technical solutions: a mechanical heat pump in combination with heat storage and discharging by PCM (phase change materials) with such temperature of melting that it is somewhat higher than the operating temperature of the working medium in the evaporation chamber.

There is a condensation-evaporation vessel, which is packed with vertical sealed containers of small diameter; these containers are filled with PCM with melting temperature that somewhat higher than the operating temperature of the evaporation chamber. The walls of the condensation-evaporation vessel can be provided with layers of thermal insulation.

The outer surfaces of the vertical sealed containers are provided with capillary coatings, which ensure constant wetting these surfaces by the liquid working medium.

The condensation-evaporation vessel is provided with an inlet connection for supply of compressed and saturated vapors of the working medium into the tank during solar hours of operation and with an outlet connection serving for return flow of the evaporated working medium into the evaporation chamber during the night time.

A mechanical compressor and a desuperheater are arranged in line and serve for pressurizing the vapors from the evaporation chamber and bringing them in the saturation state.

The desuperheater is fed by the liquid working medium pumped from the evaporation chamber by a second auxiliary pump.

The outlet connection of condensation-evaporation vessel is in fluid communication with the evaporation chamber through a control valve regulating a desirable pressure in the evaporation chamber.

The photovoltaic cells, which are mounted on the outer surface of the large-size metal plate, can be provided with a displaceable screen allowing diminishment of heat losses by radiation and natural convection to the surroundings during the night time.

The heat sink system operates in following manner: the liquid working medium, which wets the rear side of the large-size metal plate, is evaporating and obtained vapors are directed into the condenser of the recuperative type with their following condensing. The condensate is returned into the evaporation chamber and fed into the upper tray; thereafter this condensate passes in zigzag flow the complete array of the trays with wetting by capillary effect the most part of the rear surface of large-size metal plate. The pressure in the interior of the evaporation chamber is regulated by adjusting the cooling rate in the condenser.

The auxiliary pumping means is supplying the liquid working medium from the bottom section of the evaporator chamber into the inlet connection serving for feeding the liquid working medium into the upper tray. It allows to compensate for the condensate deficiency caused by condensation of the vaporous working medium on the walls of the evaporation chamber itself.

In the other version of this invention, the liquid working medium fills the evaporation chamber until such level, that the lower section of the capillary coating is submerged into the liquid working medium. For certain technical parameters of the evaporation chamber pumping ability of the capillary coating compensates for the condensate deficiency caused by condensation of the vaporous working medium on the walls of the evaporation chamber itself.

It should be noted that energizing the electrical heater can ensure this compensation as well; however, from an energetic point of view, application of the auxiliary pumping means is preferable.

At the night time the desired pressure in the evaporation chamber is established by latent heat of soldering of PCM in the vertical containers and, if it is needed, by an electrical heater installed in the bottom section of the evaporation chamber.

Operation of the condensation-evaporation vessel in the second version is outlined above.

There is a third version of the two-phase thermo-siphon design; this version comprises additionally an intervening container with a level gauge. The liquid working medium is pumped by the auxiliary pumping means into the intervening container until a certain height in it, and is discharged into a distributor of the evaporation chamber via a control cock. The rate of pumping the liquid working medium is significantly lower, than the rate of the condensed working medium supplied from the condenser. However, in the beginning period of operation of the photovoltaic receiver since advent of solar radiation, the control cock is open maximally in order to provide intensive wetting of the entire capillary coating of the large-size metal plate. In such a way, application of the auxiliary pump with the control valve allows to obviate usage of trays and ensures wetting the entire capillary coating of the large-size metal plate even for deviations in equal distribution of the liquid working medium across the width of the large-size metal plate and the condensate deficiency caused by condensation of the vaporous working medium on the walls of the evaporation chamber itself.

The rear side of the large-size metal plate of the evaporation chamber can be provided with an array of vertical metal ribs, which allow to diminish deviations in distribution

### BRIEF DESCRIPTION OF THE SEVERAL VIEWS OF THE DRAWING

FIG. 1 shows a general view of a solar power station with photovoltaic cells installed on a tower and an array of heliostats, which concentrate solar radiation on the photovoltaic cells.

FIG. 2 shows a rear side of a large-size metal plate; the forward side of this metal plate serves for installation of the photovoltaic cells.

FIG. 3a shows a vertical cross-section of a first version of an evaporation chamber, condenser and an auxiliary appliances, which serve as a heat sink for cooling the photoelectrical cells.

FIG. 3b shows a vertical cross-section of a first version of an evaporation chamber, condenser and an auxiliary appliances, which serve as a heat sink for cooling the photoelectrical cells; this first version includes an auxiliary pumping means arranged outside the evaporation chamber.

FIG. 4a shows a vertical cross-section of a second version of an evaporation chamber, condenser and an auxiliary appliances, which serve as a heat sink for cooling the photoelectric cells.

FIG. 4b shows a vertical cross-section of a second version of an evaporation chamber, condenser and an auxiliary appliances, which serve as a heat sink for cooling the photoelectric cells; this second version includes an auxiliary pumping means arranged outside the evaporation chamber.

FIG. 5 shows a vertical cross-section of a third version of the evaporation chamber, condenser, an intervening container, the auxiliary pump and auxiliary appliances, which serve as a heat sink for cooling the photoelectric cells.

FIGS. 6a and 6b show a back view of the large-size metal plate and its vertical transverse cross-section.

FIGS. 7a and 7b show a back view of the large-size metal plate and its vertical transverse cross-section; the back side of the large-size metal plate is provided with vertical ribs.

### DESCRIPTION OF PREFERRED EMBODIMENTS

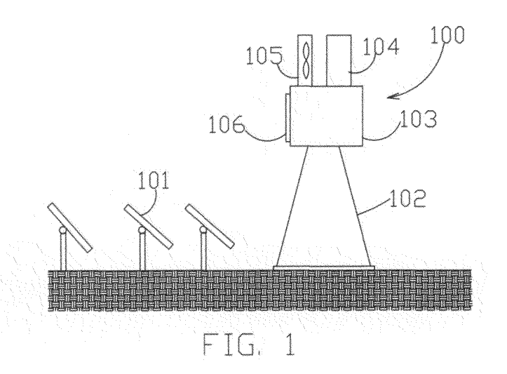

FIG. 1 shows a general view of a solar power station with photovoltaic cells installed on a tower and an array of heliostats, which concentrate solar radiation on the photovoltaic cells.

The solar power station comprises: heliostats 101; tower 102; a two-phase thermo-siphon 100, which consists of an evaporation chamber 103 with photovoltaic cells 106 installed on the outer surface of the forward wall of the evaporation chamber 103, fan 105 and condenser 104.

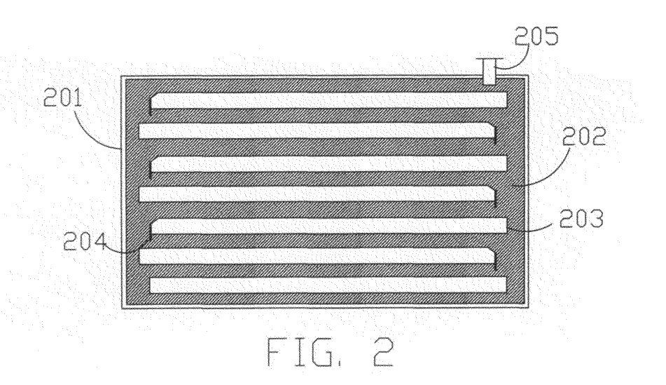

FIG. 2 shows a rear side of a large-size metal plate; the forward side of this metal plate serves for installation of the photovoltaic cells.

It comprises: the metal plate 201 with a porous capillary coating 202 on its rear side; a multistage array of trays 203 with downcomers 204; an inlet connection 205.

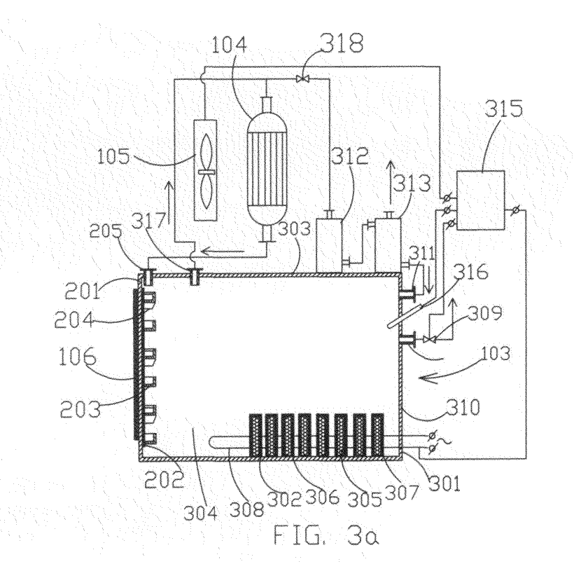

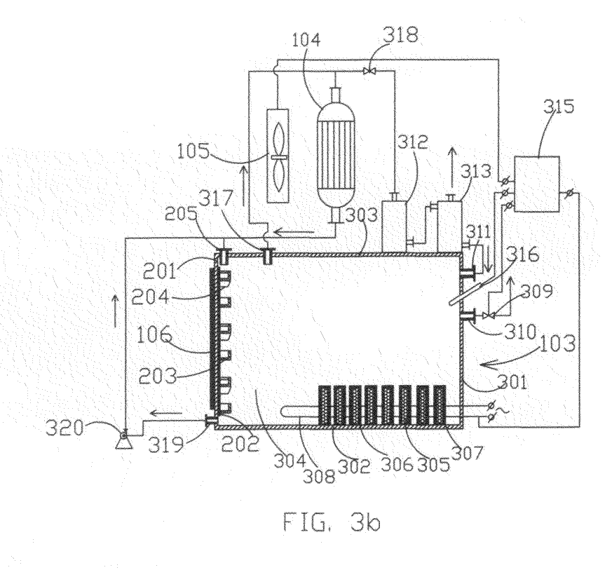

FIG. 3a shows a vertical cross-section of a first version of an evaporation chamber, condenser and an auxiliary appliances, which serve as a heat sink for cooling the photoelectrical cells.

It comprises: the evaporation chamber 103; fan 105; condenser 104; a vacuum pump 312; cooler-separator 313; control block 315.

The evaporation chamber consists of following components: the forward metal plate 201 with photovoltaic cells 106 installed on its external side and capillary coating 202 on its internal side; the multistage array of trays 203 with downcomers 204 mounted on the rear side of the forward metal plate 201;

a lateral wall 304, an upper and bottom walls 303 and 302, and a rear wall 301; an inlet connection for supply of liquid working medium into the upper tray 203; an outlet connection for removal of the gaseous working medium from the evaporation chamber 103; an inlet connection 311 for recovery of the condensed working medium into the evaporation chamber; manometer 316; an outlet connection 310 with a safety valve 309, which is mounted on this outlet connection 310; an electrical heater 308 arranged in the lower section of the evaporation chamber 103; an array of oblong sealed containers 306 filled with PCM 305 and a capillary coatings 307 on their outer surfaces. This PCM has a melting point somewhat lower than the operating temperature of the evaporation chamber 103 at sunny hours.

Condenser 104, which is in fluid communication with the outlet connection 317 and the inlet connection 205, serves for condensing vapors of the working medium removed from the evaporation chamber 103.

Fan 105 supplies a cooling air into condenser 104.

A vacuum pump 312 and condenser-separator 313 are energized during beginning operation of the heat sink system with allowing to withdraw non-condensable gases (air) via valve 318 from the interior of the evaporation chamber 103 and condenser 104.

Operation of the entire heat sink system and its elements such as the electrical heater 308, fan 105, and valve 318 are regulated by a control block according to value of internal pressure measured by manometer 316 and presence of non-condensable gases in the interior of the evaporation chamber 103 and condenser 104.

The heat sink system operates in a following manner: supply of the liquid working medium into the upper tray 203 allows wetting entire capillary coating 202 of the metal plate 201. It ensures effective cooling of photovoltaic cells 106 installed on the outer surface of this metal plate 201.

The evaporated working medium is expelled via the outlet connection 318 into condenser 104.

The condensed working medium is returning into the evaporation chamber 103 via the inlet connection 205.

PCM 305, which is filled in the oblong sealed containers 306, is melting during sunny hours at the expense of latent heat condensation of the working medium vapors on the outer surface of the oblong sealed containers 306. At the night time molten PCM is solidifying with release of the latent heat of solidification and evaporating the liquid working medium from the external capillary coatings 307.

FIG. 3b shows a vertical cross-section of a first version of an evaporation chamber, condenser and an auxiliary appliances as in FIG. 3a with two additional units: a lower outlet connection 319 and a first auxiliary pump 320.

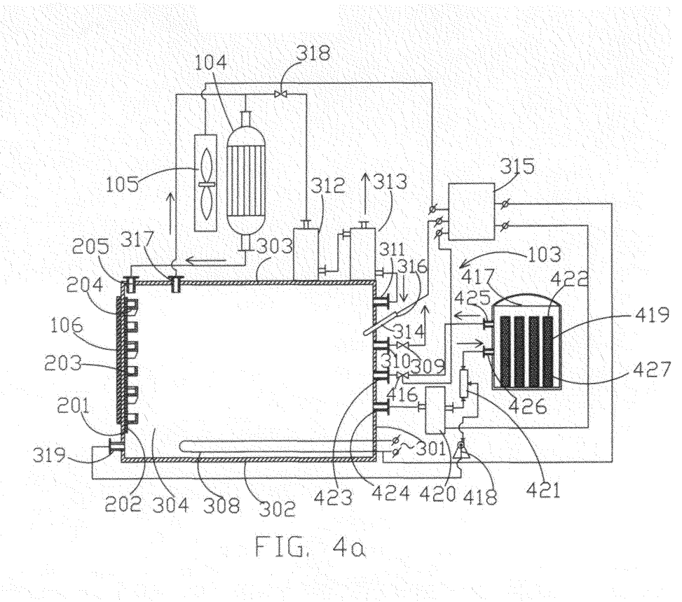

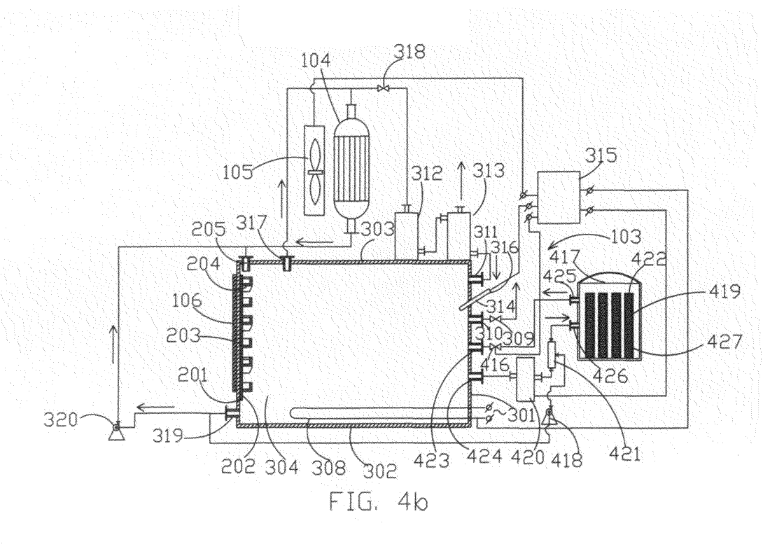

FIG. 4a shows a vertical cross-section of a second version of an evaporation chamber, condenser and an auxiliary appliances, which serve as a heat sink for cooling the photoelectrical cells.

It comprises: the evaporation chamber 103; fan 105; condenser 104; a vacuum pump 312; cooler-separator 313; control block 315.

The evaporation chamber consists of following components: the forward metal plate 201 with photovoltaic cells 106 installed on its external side and capillary coating 202 on its internal side; the multistage array of trays 203 with downcomers 204 mounted on the rear side of the forward metal plate 201;

a lateral wall 304, an upper and bottom walls 303 and 302, and a rear wall 301; an inlet connection for supply of liquid working medium into the upper tray 203; an outlet connection for removal of the gaseous working medium from the evaporation chamber 103; an inlet connection 311 for recovery of the condensed working medium into the evaporation chamber; manometer 316; an outlet connection 310 with a safety valve 309, which is mounted on this outlet connection 310; an electrical heater 308 arranged in the lower section of the evaporation chamber 103.

Fan 105 supplies a cooling air into condenser 104.

A vacuum pump 312 and condenser-separator 313 are energized during beginning operation of the heat sink system and allows to withdraw non-condensable gases (air) via valve 318 from the interior of the evaporation chamber 103 and condenser 104.

There is a sealed vessel 417 with an array of oblong sealed containers 419 filled with PCM 422 and a capillary coatings 427 on their outer surfaces. This PCM has a melting point somewhat higher than the operating temperature of the evaporation chamber 103 at sunny hours.

The vapors of the working medium are removed at the sunny hours via the outlet connector 424 from the evaporation chamber 103 and compressed by compressor 420. The superheated pressurized vapors are brought into saturation state in desuperheater 421 by atomization of the liquid working medium, which is supplied by pump 418 from an inlet connection 319 in the bottom section of the evaporation chamber 103.

In such a way, the latent condensation heat of the working medium vapors is transformed into the latent heat of melting of PCM in the oblong sealed containers 419.

At the night time the molten PCM 422 is solidifying with release of the latent heat of solidification and evaporating of the liquid working medium from the external capillary coatings 427. The working medium vapors are entering into the evaporation chamber via the outlet connection 425 of vessel 417, a control valve 416 and an inlet connection 423 of the evaporation chamber 103.

The heat sink system operates in a following manner: supply of the liquid working medium into the upper tray 203 allows wetting entire capillary coating 202 of the metal plate 201. It ensures effective cooling of photovoltaic cells 106 installed on the outer surface of this metal plate 201.

The evaporated working medium is expelled via the outlet connection 318 into condenser 104.

The condensed working medium is returning into the evaporation chamber 103 via the inlet connection 205.

PCM 422, which is filled in the oblong sealed containers 419, is melting during sunny hours at the expense of latent heat condensation of the working medium vapors on the outer surface of the oblong sealed containers 419. At the night time molten PCM is solidifying with release of the latent heat of solidification and evaporating of the liquid working medium from the external capillary coatings 427.

Entrance of hot vapors of the working medium into the evaporation chamber 103 at the night time allows to keep such pressure in the evaporation chamber 103, which is very close to atmospheric pressure.

FIG. 4b shows the same as FIG. 4a with an additional pump 320 for supplying the liquid working medium in the inlet connection 205.

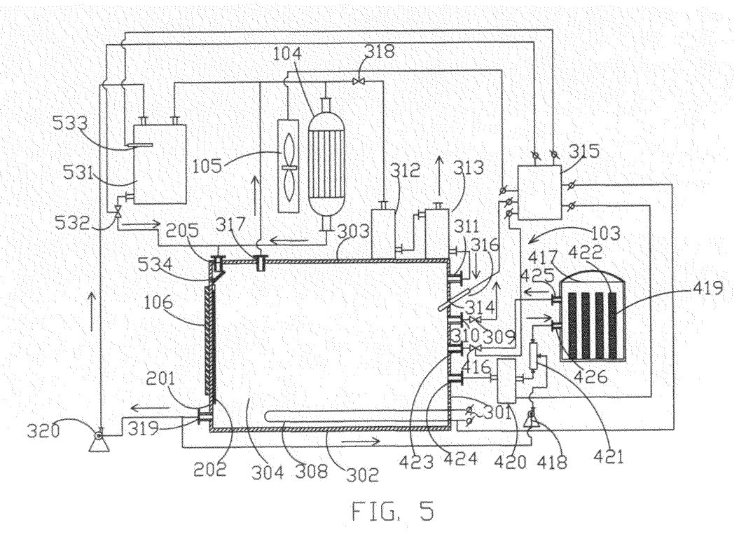

FIG. 5 shows a vertical cross-section of a third version of the evaporation chamber, condenser, an intervening container and auxiliary appliances, which serve as a heat sink for cooling the photoelectrical cells. It comprises: the evaporation chamber 103; fan 105; condenser 104; a vacuum pump 312; cooler-separator 313; control block 315.

The evaporation chamber consists of following components: the forward metal plate 201 with photovoltaic cells 106 installed on its external side and capillary coating 202 on its internal side; distributor 534 of the liquid working medium;

a lateral wall 304, an upper and bottom walls 303 and 302, and a rear wall 301; an inlet connection for supply of liquid working medium into the upper tray 203; an outlet connection for removal of the gaseous working medium from the evaporation chamber 103; an inlet connection 311 for recovery of the condensed working medium into the evaporation chamber; manometer 316; an outlet connection 310 with a safety valve 309, which is mounted on this outlet connection 310; an electrical heater 308 arranged in the lower section of the evaporation chamber 103.

Fan 105 supplies a cooling air into condenser 104.

A vacuum pump 312 and condenser-separator 313 are energized during beginning operation of the heat sink system and allows to withdraw non-condensable gases (air) via valve 318 from the interior of the evaporation chamber 103 and condenser 104.

There is a sealed vessel 417 with an array of oblong sealed containers 419 filled with PCM 422 and a capillary coatings 427 on their outer surfaces. This PCM has a melting point somewhat higher than the operating temperature of the evaporation chamber 103 at sunny hours.

The vapors of the working medium are removed at the sunny hours via the outlet connector 424 from the evaporation chamber 103 and compressed by compressor 420. The superheated pressurized vapors are brought into saturation state in desuperheater 421 by atomization of the liquid working medium, which is supplied by pump 418 from an inlet connection 319 in the bottom section of the evaporation chamber 103.

The additional pump 320 supplies the liquid working medium into an intervening container 531 with a level gauge 533. Supply of the liquid working medium into the inlet connection 295 is regulated by a control cock 532.

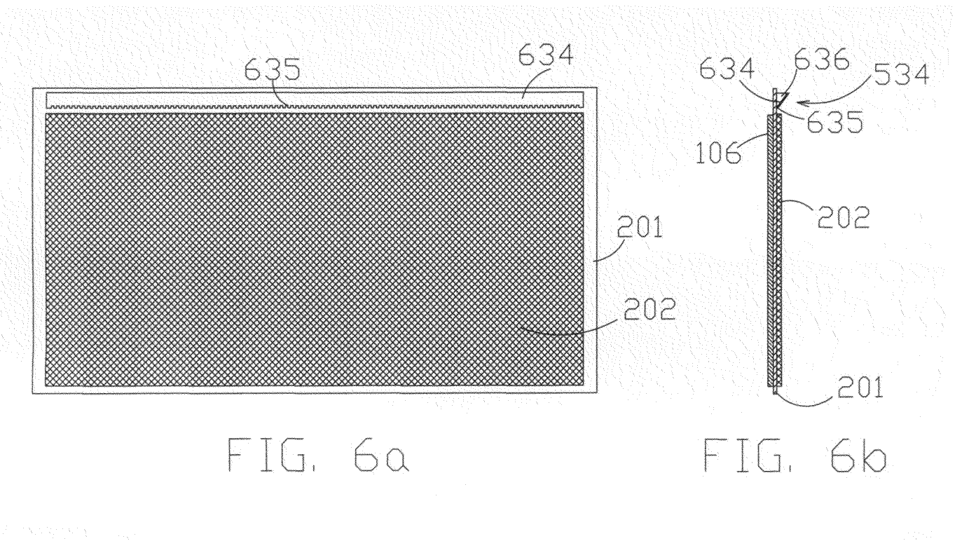

FIGS. 6a and 6b show a back view of the large-size metal plate and its vertical transverse cross-section.

It comprises the photovoltaic cells 106, the large-size metal plate 201 with the capillary coating 202, a metal strip 634 with a lower toothed edge 635, face plane wall 636; the upper section of the large-size metal plate 201, a metal strip 634 with a lower toothed edge 635 and face plane wall 636 form distributor 534.

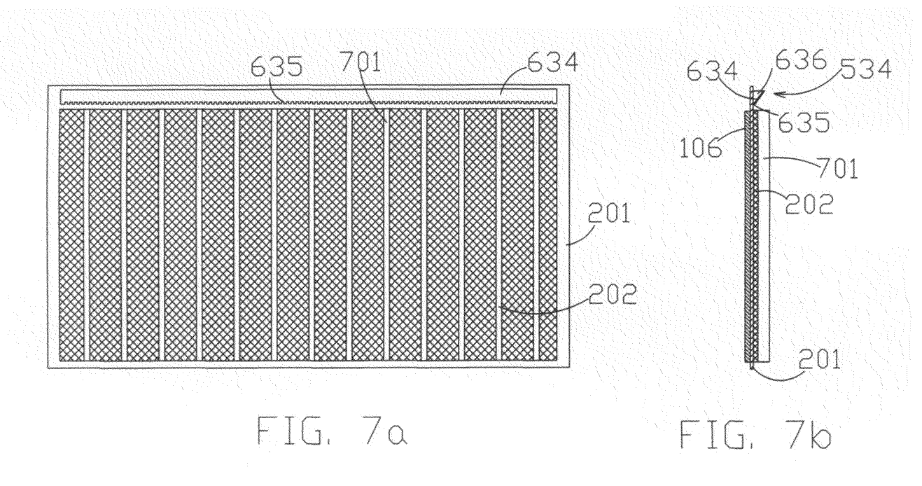

FIGS. 7a and 7b show a back view of the large-size metal plate and its vertical transverse cross-section having the same parts as in FIGS. 6a and 6b with vertical ribs 701.

1. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit; said heat sink unit comprises an evaporator chamber and a condenser being in fluid communication with said evaporation chamber; said condenser is positioned at somewhat higher level regarding said evaporation chamber; said evaporation chamber comprises:
a large-size metal plate with photovoltaic cells installed on its forward side, the rear side of this metal plate is provided with a capillary structure;
a set of trays, which is mounted on the rear side of said large-size metal plate in such a way that the forward walls of said trays are formed by sections of said large-size metal plate with its capillary structure;
overflow elements, which are parts of construction of said trays; said overflow elements ensure filling all said trays with liquid working medium;
said evaporation chamber includes as well:
lateral and a rear walls with an outlet connection for removal of vapors of the working medium and at least one inlet connection for supply of said liquid working medium into said upper tray;
a safety valve (or valves), which provides fluid communication of said evaporation chamber interior with the atmosphere in the case of significant deviation of pressure in the interior of said evaporation chamber from the atmospheric pressure;
an electrical heater arranged in the bottom section of said evaporation chamber;
said condenser is designed as a heat exchanger of recuperative type; said condenser is provided with inlet and outlet connections, which are in fluid communication with said outlet and inlet connection of said evaporation chamber;
a vacuum pump and a cooler-separator, which are in fluid communication with said condenser and said evaporation chamber and serve for periodical removal of non-condensable gases from the interiors of said condenser and evaporation chamber;
a pressure gauge, which is measuring the internal pressure in said evaporation chamber;
a coolant serving for cooling and condensation of said working medium vapors in said condenser;
a control block with regulates the rate of cooling said working medium vapors in said condenser and energizing said electrical heater.

2. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit as claimed in claim 1, wherein there is an array of a vertical sealed containers mounted on the lower lateral wall of the evaporation chamber; said sealed containers are filled with phase change material (PCM) with melting point some Celsius degree lower than the operating temperature of the working medium; the outer surfaces of said sealed containers are provided with capillary coatings. 3. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit as claimed in claim 1, wherein the coolant is surrounding air.

4. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit as claimed in claim 1, wherein the coolant is cooling water.

5. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit as claimed in claim 1, wherein the lateral, rear and bottom walls of the evaporation chamber are provided with layers of thermal insulation.

6. A large-size photovoltaic receiver of a tower-type solar power station with application of an array of heliostats for concentration of solar radiation on said large-size photovoltaic receiver; said large-size photovoltaic receiver is designed as sink unit with photovoltaic cells mounted on the outer side of said heat sink unit as claimed in claim 1, wherein maintaining the evaporation pressure in the evaporation chamber is based on two technical solutions: 1. mechanical heat pumping and 2. heat storage-discharging by PCM (phase change materials) with such temperature of melting which somewhat higher than the operating temperature of the working medium in the evaporation chamber.

7. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit as claimed in claim 6, wherein the mechanical heat pumping is realized as a compressor a desuperheater and a pump, which feeding the liquid working medium from the bottom section of said evaporation chamber into said desuperheater; said compressor and said desuperheater are arranged in line; said compressor is in fluid communication with the evaporation chamber, and said desuperheater is in fluid communication with a condensation-evaporation vessel, which realizes heat storage-discharge by PCM; said condensation-evaporation vessel is packed with vertical sealed containers of small diameter; said vertical sealed containers are filled with said PCM with melting temperature which somewhat higher than the operating temperature of said evaporation chamber; the outer surfaces of said vertical sealed containers are provided with capillary coating; the interior of said condensation-evaporation vessel is in fluid communication with said evaporation chamber via a control valve.

8. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit as claimed in claim 1, wherein the outer side of the large-size metal plate is provided with stiffening ribs

9. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit as claimed in claim 1, wherein the evaporator chamber is provided with a lower outlet connection, and there is a pumping means in fluid communication with said lower outlet connection; said pumping means serves for compensation of condensate losses in delivery of condensate on the working medium from the condenser into the evaporation chamber.

10. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit;
said heat sink unit comprises an evaporator chamber and a condenser being in fluid communication with said evaporation chamber; aid condenser is positioned at somewhat higher level regarding said evaporation chamber; said evaporation chamber comprises:
a large-size metal plate with photovoltaic cells installed on its forward side, the rear side of this metal plate is provided with a capillary structure;
a distributor of the returned liquid working medium from said condenser; said distributor is supplying the liquid working medium on the internal side of said large-size metal plate;
said evaporation chamber includes as well lateral and a rear walls with an outlet connection for removal of vapors of the working medium and at least one inlet connection for supply of said liquid working medium into said distributor;
a safety valve (or valves), which provides fluid communication of said evaporation chamber interior with the atmosphere in the case of significant deviation of pressure in the interior of said evaporation chamber from the atmospheric pressure;
an electrical heater arranged in the bottom section of said evaporation chamber;
said condenser is designed as a heat exchanger of recuperative type; said condenser is provided with inlet and outlet connections, which are in fluid communication with said outlet and inlet connection of said evaporation chamber;
a vacuum pump and a cooler-separator, which are in fluid communication with said condenser and said evaporation chamber and serve for periodical removal of non-condensable gases from the interiors of said condenser and evaporation chamber;
a pressure gauge, which is measuring the internal pressure in said evaporation chamber;
a coolant serving for cooling and condensation of said working medium vapors in said condenser;
a control block, which regulates the rate of cooling said working medium vapors in said condenser and energizing said electrical heater.

11. A large-size photovoltaic receiver of a tower-type solar power station with application of an array of heliostats for concentration of solar radiation on said large-size photovoltaic receiver as claimed in claim 10, wherein there is a pumping means, which is supplying the liquid working medium into an intervening container; an outlet connection of said intervening container is in fluid communication with the inlet connection of the evaporation chamber via a control cock.

12. A large-size photovoltaic receiver of a tower-type solar power station with application of an array of heliostats for concentration of solar radiation on said large-size photovoltaic receiver; said large-size photovoltaic receiver is designed as a heat sink unit with photovoltaic cells mounted on the outer side of said heat sink unit as claimed in claim 1, wherein the photovoltaic cells are provided with displaceable screen.
